(19) United States
(12) Patent Application Publication
(10) Pub. No.: US 2013/0316279 A1
(43) Pub. Date: Nov. 28, 2013

(54) Organic Semiconductor Composition

(71) Applicant: CENTRAL GLASS COMPANY, LIMITED, Ube-shi (JP)

(72) Inventors: Hideaki IMURA, Iruma-gun (JP); Masamune Okamoto, Fujimino-shi (JP); Naoto Takada, Iruma-gun (JP)

(73) Assignee: Central Glass Company, Limited, Ube-shi (JP)

(21) Appl. No.: 13/851,692

(22) Filed: Mar. 27, 2013

(30) Foreign Application Priority Data
May 23, 2012 (JP) 2012-117535
May 23, 2012 (JP) 2012-117536

(51) Int. Cl. H01L 51/00; C09D 11/00

(52) U.S. Cl. CPC H01L 51/0073; H01L 51/0067; H01L 51/0071; C09D 11/30
USPC 430/72; 252/500; 430/75; 430/77

(57) ABSTRACT

A composition according to the present invention contains at least a triarylamine compound and at least one bicyclic compound selected from the group consisting of those of the general formulas [1] to [4], wherein the triaryl amine compound is dissolved in the at least one bicyclic compound

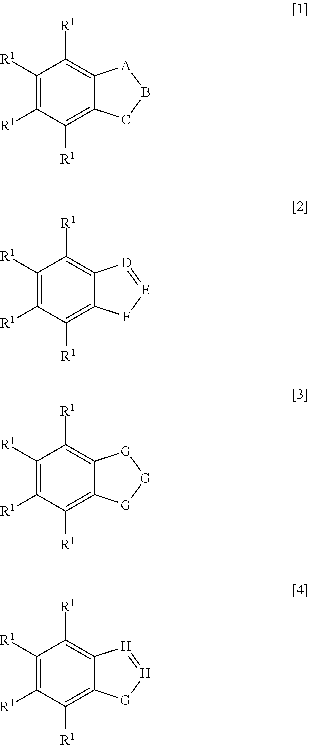

where R¹ each independently represents a hydrogen atom, a methyl group, an ethyl group, a methoxy group, an ethoxy group, a fluorine atom or a chlorine atom; A, B, C and F each independently represents either —CR²₂—, —O— or —NR²—; D and E each independently represents either —CR²═ or —N═; G represents —CR²₂—; H represents —CR²═; and R² represents a hydrogen atom, a methyl group or a halogen atom.

### FIELD OF THE INVENTION

The present invention relates to an organic semiconductor composition containing a high concentration of triarylamine compound that is effective as charge transfer materials of electrophotographic photoreceptors, charge transfer materials of organic electroluminescence elements or organic semiconductors, and the like.

### BACKGROUND OF THE INVENTION

Aromatic amine compounds such as N,N′-diphenyl-N,N′-di(m-tolyl)benzidine (TPD) and N,N-diphenyl-N,N-bis(1-naphthyl)-4,4-diaminobiphenyl (α-NPD) are used in various electron devices because of their high charge transfer functions. For example, the aromatic amine compounds are known to be useful as charge transfer materials of electrophotographic photoreceptors in copiers, printers etc., charge transfer materials or luminous materials of organic electroluminescence elements (organic EL elements) and intermediates for charge transfer materials, luminous materials etc. and are particularly suitable for use as positive hole transfer materials. Patent Document 1 discloses various kinds of aromatic amine compounds as charge transfer materials for formation of positive hole transfer layers, that is, positive hole transfer materials.

However, the highly charge-transferable aromatic amine compounds are potentially low in solubility in ordinary organic solvents. In particular, triarylamine compounds having a plurality of triarylamine structures as typified by α-NPD are low in solubility and difficult to handle in synthesis/purification of triarylamine compounds and in preparation of triarylamine compositions. If molecular design of the charge transfer material is performed in view of solubility, there arises a problem of deterioration in the charge transfer function of the charge transfer material. There is also a problem that, in the case of preparing a coating composition or the like using an ordinary solvent in which the solubility of the triarylamine compound is low, the triarylamine compound gets deposited during storage so that the coating composition or the like is short in pot life.

Patent Document 2 discloses a technique for forming a luminescent layer by dissolving an anthracene derivative, which mainly imparts a luminescent function, in a solvent of specific structure. In one embodiment of Patent Document 2, the luminescent anthracene derivative is used as a host molecule in combination with a highly charge-transferable triarylamine compound as a guest molecule. It is further described in Patent Document 2 that the concentration of the anthracene derivative in the solvent is 0.01 mass % or more (preferably, 0.05 mass % or more); and the amount of the triarylamine compound added is preferably 0.01 to 20 mass % relative to the mass of the anthracene derivative. The triarylamine compound is added in an amount of 0.2 mass % relative to the solvent in the working examples of this patent document.

### PRIOR ART DOCUMENTS

Patent Document 1: Japanese Laid-Open Patent Publication No. H10-36832
Patent Document 2: International Application Publication No. WO 2010/032447 A1

### SUMMARY OF THE INVENTION

It cannot however be said that, in Patent Document 2, the amount of the triarylamine compound dissolved in the solvent is sufficient for synthesis/purification of triarylamine compound or preparation of triarylamine composition. Further, the anthracene derivative is used as the main solute in Patent Document 2. It is not obvious in Patent Document 2 whether it is possible to prepare a solution (composition) using the triarylamine compound as the main solute as in the case of the present invention and whether the thus-obtained solution has good coating performance and operability.

It is accordingly an object of the present invention to find out a solvent capable of dissolving therein a sufficient concentration of charge-transferable triarylamine compound for synthesis/purification of triarylamine compounds and preparation of triarylamine compositions and to thereby provide a stable composition in which a triarylamine compound is sufficiently dissolved.

In order to achieve the above object, the present inventors have tried to dissolve triarylamine compounds in various solvents disclosed in Patent Document 2 as suitable anthracene derivative-dissolving solvents for formation of luminescent layers of organic EL elements. The present inventors have however reached a conclusion that the triarylamine compounds do not show sufficient solubility in those suitable solvents such as 2-ethyltoluene, 1,2-methylenedioxybenzene, 1,2,4-trimethylbenzene and 1,2,3-trimethylbenzene (see Comparative Examples 1 to 4).

In general, a host molecule and a guest molecule need to be dispersed uniformly in a solution in order to form a film with stable quality. For this reason, it is desirable to select and use the guest molecule highly compatible with the host molecule. It is probable in Patent Document 2 that the anthracene derivative host molecule functions to increase the solubility of the triarylamine guest molecule.

The present inventors have found, as a result of extensive molecular design, that: bicyclic compounds having condensed structures of 5-membered electron-withdrawing oxygen- or nitrogen-containing rings and π-conjugated benzene rings and bicyclic compounds having condensed structures of 5-membered hydrocarbon rings and π-conjugated benzene rings (hereinafter occasionally just referred to as “bicyclic compounds”), even when used alone, are uniquely capable of dissolving triarylamine compounds; and the boiling points of these bicyclic compounds are in a suitable range for reaction/purification of triarylamine compounds and preparation of triarylamine compositions. More specifically, it has been found that bicyclic compounds of the general formulas [1] to [4] are suitable solvents for dissolving therein triarylamine compounds. The present invention is based on the above findings.

Namely, the present invention includes the following aspects.

[Inventive Aspect 1]

A composition comprising at least a triarylamine compound and at least one bicyclic compound selected from the group consisting of those of the general formulas [1] to [4], wherein the triaryl amine compound is dissolved in the at least one bicyclic compound

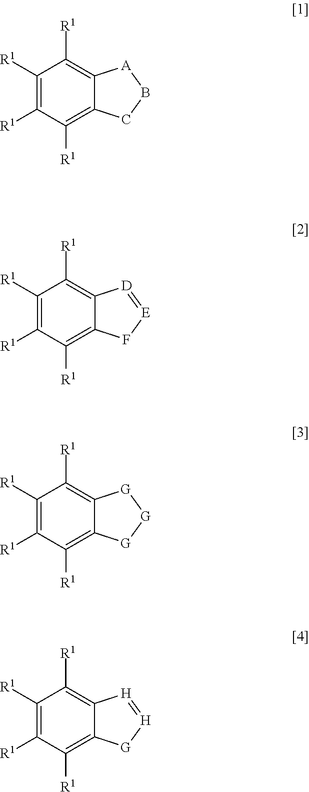

where R¹ each independently represents a hydrogen atom, a methyl group, an ethyl group, a methoxy group, an ethoxy group, a fluorine atom or a chlorine atom; A, B, C and F each independently represents either —CR²₂—, —O— or —NR²—; D and E each independently represents either —CR²═ or —N═; G represents —CR²₂—; H represents —CR²—; and R² represents a hydrogen atom, a methyl group or a halogen atom.

[Inventive Aspect 2]

The composition according to Inventive Aspect 1, wherein the triarylamine compound has two or more tertiary nitrogen atoms.

[Inventive Aspect 3]

The composition according to Inventive Aspect 2, wherein different two of the tertiary nitrogen atoms of the triarylamine compound are bonded by any of structures of the following formulas (a) to (e)

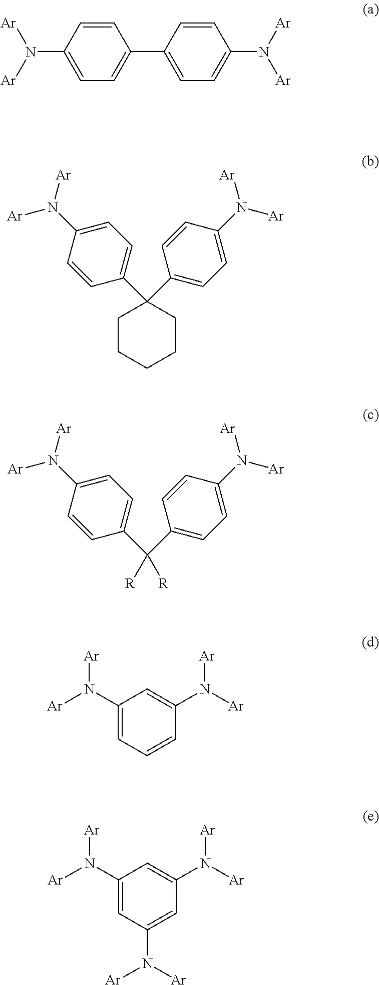

where R represents a C₁-C₈ alkyl group; and Ar each independently represents an aryl group and can be of the same kind or different kinds.

[Inventive Aspect 4]

The composition according to any one of Inventive Aspects 1 to 3, wherein the bicyclic compound has a boiling point of 150 to 250° C.

[Inventive Aspect 5]

The composition according to any one of Inventive Aspects 1 to 4, wherein the triarylamine compound is a charge transfer material.

[Inventive Aspect 6]

The composition according to any one of Inventive Aspects 1 to 5, wherein the composition is a coating material for forming a charge transfer layer or a positive hole transfer layer.

[Inventive Aspect 7]

The composition according to Inventive Aspect 6, wherein the coating material is for ink-jet process.

[Inventive Aspect 8]

The composition according to any one of Inventive Aspects 1 to 4, wherein the composition is for use in reaction or purification.

[Inventive Aspect 9]

The composition according to any one of Inventive Aspects 1 to 8, wherein the triarylamine compound is contained in an amount of 0.01 to 2 parts by mass per 100 parts by mass of the at least one bicyclic compound.

[Inventive Aspect 10]

The composition according to any one of Inventive Aspects 1 to 9, wherein the triarylamine compound is contained in an amount of at least 0.5 mass %.

[Inventive Aspect 11]

The composition according to any one of Inventive Aspects 1 to 10, wherein the at least one bicyclic compound is one kind of compound or two or more kinds of compounds selected from the group consisting of benzofuran, 2,3-dihydrobenzofuran, benzo[d][1,3]dioxole, 1,3-dihydroisobenzofuran, 1H-isoindole, 3H-indole, benzo[d]oxazole, 3H-indazole, 2-methylisoindoline, 1-methylindoline, indene and indane.

In the present specification, the term “solvent” refers to a liquid capable of dissolving therein a solute (gas, liquid or solid) for the formation of a solution. The term “main solvent” refers to a liquid that is the highest in content among solvents. The term “dissolved” means that a solute (triarylamine compound) is dispersed in a solvent to form a homogeneous system where no insoluble matter is seen by visual inspection. Further, the term “sufficiently dissolved” means that a solute (triarylamine compound) is dissolved in an amount of 0.5 mass % or more, preferably 1.0 mass % or more, in a solvent.

In the present invention, the bicyclic compound used as the solvent is capable of sufficiently dissolving therein the triarylamine compound. It is therefore possible to efficiently perform recrystallization or column purification of the triarylamine compound. It is further possible to prepare a stable solution with a high concentration of triarylamine compound and efficiently apply a coating with less defects. As the solubility of the triarylamine compound in the bicyclic compound is very high, the thus-obtained triarylamine composition is long in pot life. The bicyclic compound used as the solvent is particularly effective in dissolving the solute (triarylamine compound) that is solid at room temperature.

### DESCRIPTION OF THE EMBODIMENTS

The present invention provides a composition containing a charge-transferable triarylamine compound or a triarylamine compound as a precursor of a charge-transferable triarylamine compound and at least one of bicyclic compounds of the general formulas [1] to [4] for dissolving therein the triarylamine compound.

As the triarylamine compound, there can be used any of those having at least one triarylamine structure, that is, at least one tertiary nitrogen atom to which three aryl groups are bonded (occasionally just referred to as “tertiary nitrogen atom”). Preferred examples of the triarylamine structure are those of the general formulas [5] to [7].

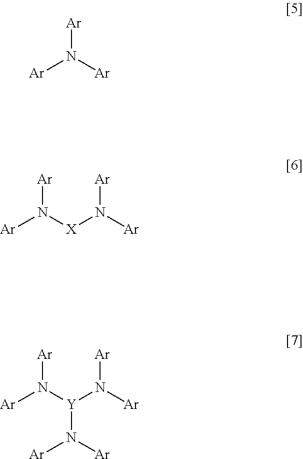

In the general formulas [5] to [7], Ar each independently represents an aryl group and can be of the same kind or different kinds; X and Y represent a divalent organic group and a trivalent organic group, respectively, and are each directly bonded to a diarylamino group (Ar₂N—).

The aryl group is preferably a phenyl group or a polycyclic aromatic hydrocarbon group such as a naphthyl group. In the case where Ar is a polycyclic aromatic hydrocarbon group, there is no particular limitation on the number of benzene rings. The number of benzene rings in Ar is generally about 1 to 6, preferably 1 to 2. A part of hydrogen atoms of the aryl group may be substituted with a substituent group. Examples of the substituent group are: C₁-C₁₆ alkyl groups such as methyl, ethyl, n-propyl, iso-propyl, n-butyl, sec-butyl, iso-butyl and tert-butyl; C₃-C₇ cycloalkyl groups such as cyclopropyl, cyclobutyl, cyclopentyl, cyclohexyl, methylcyclopropyl, methylcyclobutyl, methylcyclopentyl and methylcyclohexyl; C₁-C₁₆ alkoxy groups such as methoxy, ethoxy, propoxy, isopropoxy, cyclopropoxy and cyclobutoxy; C₂-C₁₆ alkenyl groups; C₃-C₁₆ polyalkoxy groups; C₆-C₉ aralkyl groups such as finyl, benzyl and phenethyl; aromatic hydrocarbon ring groups; and aromatic heterocyclic groups.

Further, any hydrogen atom or atoms of the triarylamine compound may be substituted with a halogen atom such as fluorine, chlorine, bromine or iodine. In this case, it is desirable to take any measure against dehalogenation, such as light shielding, because the halogen-substituted triarylamine compound can undergo dehalogenration by the action of light, heat etc. The halogen-substituted triarylamine compound is however useful as an intermediate for synthesis of charge-transferable triarylamine compounds.

The triarylamine compound varies in solubility according to the kinds of aryl groups and the number of tertiary nitrogen atoms in the molecule. The triarylamine compound having one tertiary nitrogen atom as typified by triphenylamine tends to be a very easy-to-dissolve solute so that, although the triarylamine compound having one tertiary nitrogen atom can be dissolved efficiently in the solvent according to the present invention, it is feasible to use any other ordinary general-purpose solvent in place of the solvent according to the present invention. On the other hand, the triarylamine compound having a plurality of tertiary nitrogen atoms as typified by α-NPD sharply decreases in solubility. The solvent according to the present invention is thus suitable for such a triarylamine compound because the triarylamine compound shows specific solubility in the solvent according to the present invention. The number of tertiary nitrogen atoms in the triarylamine compound is generally about 1 to 10, preferably 2 to 6, more preferably 2 to 4 although there is no particular limitation on the number of tertiary nitrogen atoms in the triarylamine compound. The triarylamine compound may be dissolved even if the number of tertiary nitrogen atoms in the triarylamine compound is 10 or more. In this case, however, there is a possibility that the resulting composition becomes short in pot life.

In the case where there exist a plurality of tertiary nitrogen atoms in the triarylamine compound, the triarylamine compound has a coupling structure in which triarylamine groups of the same kind or different kinds are coupled together. In view of ease of synthesis, the triarylamine compound is preferably a coupling compound having triarylamine groups of the same kind. There is no particular limitation on the coupling structure between the triarylamine groups, i.e., the structures of the organic groups X and Y in the general formulas [6] and [7]. Preferred examples of the triarylamine coupling structure are those of the formulas (a) to (e) indicated in Scheme 1. In Scheme 1, R represents a C₁-C₈ alkyl group; and Ar has the same definition as in the general formula [4] and [5].

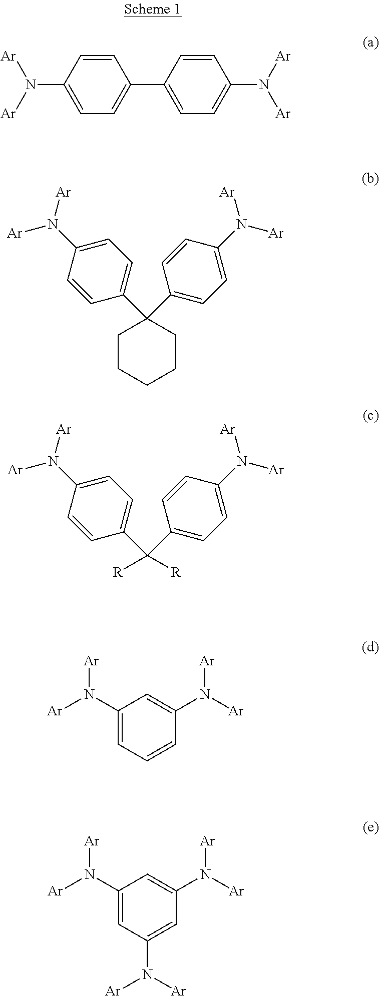

Among the above coupling structures, particularly preferred are those having a biphenyl bond between tertiary nitrogen atoms as represented by the formula (a).

If the molecular weight of the triarylamine compound is less than 400 or exceeds 2000, the triarylamine compound may not provide a sufficient charge transfer function or may cause an insufficient pot life (solution stability). The molecular weight of the triarylamine compound is thus preferably 400 to 2000, more preferably 480 to 1500.

Specific examples of the triarylamine compound usable in the present invention are highly charge-transferable triarylamines such as α-NPD, TPD, TPAC, PDA and m-MTDATAT (see Scheme 2). These compounds can suitably be used in the present invention as each of these compounds is commercially available as reagents and put into practical use as charge transfer materials of organic EL elements etc. There can also preferably be used triarylamine compounds obtained by substitution of a part of hydrogen atoms of the above triarylamine compounds with: C₁-C₁₆ alkyl groups such as methyl, ethyl, n-propyl, iso-propyl, n-butyl, sec-butyl, iso-butyl and tert-butyl; C₃-C₇ cycloalkyl groups such as cyclopropyl, cyclobutyl, cyclopentyl, cyclohexyl, methylcyclopropyl, methylcyclobutyl, methylcyclopentyl and methylcyclohexyl; C₁-C₁₆ alkoxy groups such as methoxy, ethoxy, propoxy, isopropoxy, cyclopropoxy and cyclobutoxy; C₂-C₁₆ alkenyl groups; C₃-C₁₆ polyalkoxy groups; C₆-C₉ aralkyl groups such as finyl, benzyl and phenethyl; aromatic hydrocarbon ring groups; and aromatic heterocyclic groups. In view of charge transfer function, the number of substituent groups on the triarylamine compound is preferably 1 to 12, more preferably 2 to 9, although the number of substituent groups on the triarylamine compound depends on the kinds of substituent groups.

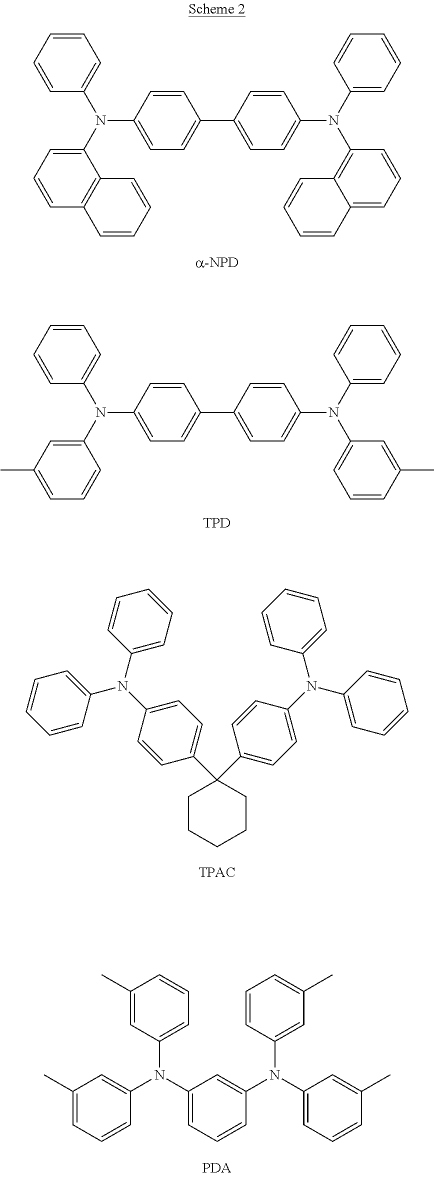

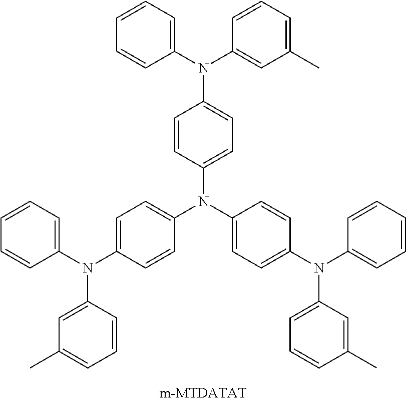 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

Next, the solvent according to the present invention will be explained below. In the present invention, at least one selected from the group of bicyclic compounds of the general formulas [1] and [2] each having a ring-condensed structure in which a benzene ring and a 5-membered ring containing at least one heteroatom are condensed and bicyclic compounds of the general formulas [3] and [4] each having a ring-condensed structure in which a benzene ring and a 5-membered hydrocarbon ring are condensed is used as a main solvent. In each of the bicyclic compounds, the 5-membered ring can be saturated or unsaturated.

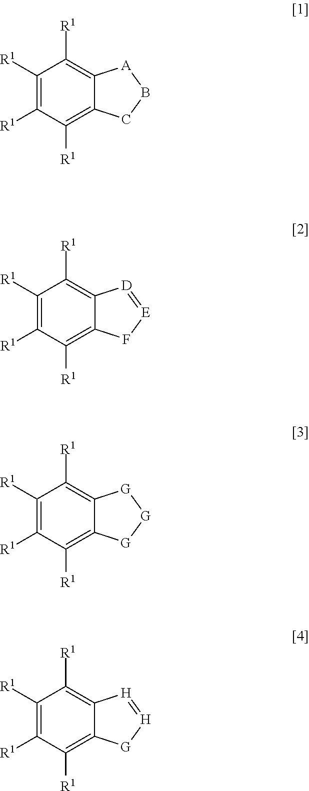

In the above formulas, R¹ each independently represents a hydrogen atom, a methyl group, an ethyl group, a methoxy group, an ethoxy group, a fluorine atom or a chlorine atom; A, B, C and F each independently represents either —CR²₂—, —O— or —NR²—; D and E each independently represents either —CR²═ or —N═; G represents —CR²₂—; H represents —CR²═; and R² represents a hydrogen atom, a methyl group or a halogen atom. In the case where the bicyclic compound contains a halogen atom such as chlorine, bromine or iodine, it is necessary to take any measure such as light shielding in view of the possibility of halogenation of the triarylamine compound by such a halogen-containing bicyclic compound under light irradiation.

Specific examples of the bicyclic compound with the 5-membered heteroatom-containing ring are compounds indicated in Scheme 3. There can also preferably be used those obtained by substitution of a part of hydrogen atoms on the 6-membered rings of the bicyclic compounds indicated in Scheme 3 with a methyl group. The number of methyl groups substituted on the 6-membered ring of the bicyclic compound is preferably 1 or 2.

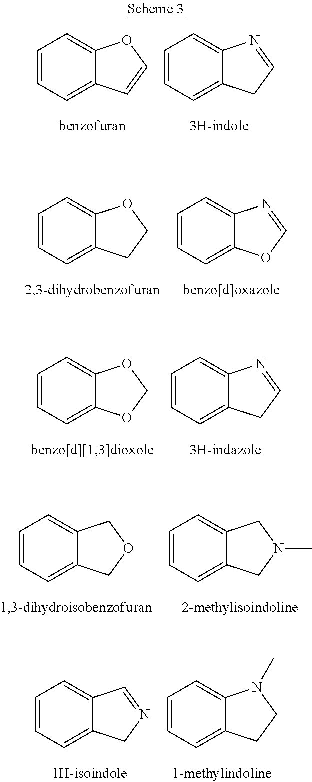

Specific examples of the bicyclic compound with the 5-membered hydrocarbon ring are compounds indicated in Scheme 4. There can also preferably be used those obtained by substitution of a part of hydrogen atoms of the bicyclic compounds indicated in Scheme 4 with a methyl group. The number of methyl groups substituted on the bicyclic compound is preferably 1 or 2.

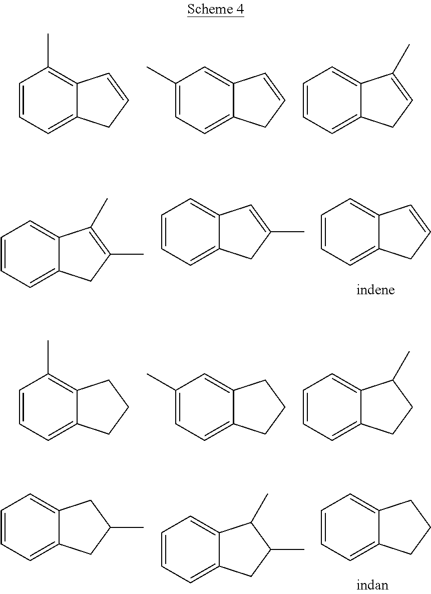

Among the above bicyclic hydrocarbon compounds, indene and indane are particularly preferred as the solvent because these bicyclic compounds are readily available and satisfy the following temperature conditions.

In any of the after-mentioned uses, there is no particular limitation on the boiling point of the bicyclic compound. Preferably, the boiling point of the bicyclic compound is 150 to 250° C. If the boiling point of the bicyclic compound is higher than 250° C., there may be a need for time to remove the bicyclic compound by volatilization. It has been confirmed as a result of researches made by the present inventors that the bicyclic compounds of the general formulas [1] to [4] each have a boiling point of 150° C. or higher.

There is no particular limitation on the lower limit of the melting point of the bicyclic compound. The upper limit of the melting point of the bicyclic compound is preferably 25° C., more preferably 15° C. There arises a need to perform dissolution operation on the bicyclic compound, notably in winter, if the melting point of the bicyclic compound is higher than 25° C.

The composition according to the present invention will be next explained in more detail below. The composition contains the triarylamine compound and the bicyclic compound, characterized in that the triarylamine compound is dissolved in the bicyclic compound. One kind of bicyclic compound or different kinds of bicyclic compounds in combination can be used as the solvent in the composition. Further, one kind of triarylamine compound or a plurality of kinds of triarylamine compounds can be used as the solute.

The component ratio of the composition can be controlled as appropriate depending on the purpose of use of the composition. In general, the triarylamine compound is contained in an amount of 0.01 to 2 parts by mass, preferably 0.1 to 1.5 parts by mass, more preferably 0.5 to 1 parts by mass, per 100 parts by mass of the bicyclic compound.

The composition may contain any other solvent in combination with the bicyclic compound. Examples of the other solvent usable in the composition are: water; aliphatic, alicyclic and aromatic hydrocarbons such as petroleum ether, n-hexane, n-heptane, cyclohexane, benzene, toluene, xylene and decalin; ethers such as diethyl ether, iisopropyl ether, methyl tert-butyl ether, methyl tert-amyl ether, dioxane, tetrahydrofuran, 1,2-dimethoxyethane, 1,2-diethoxyethane and anisole; alcohols such as methanol, ethanol, n-propanol, isopropanol, n-butanol, i-butanol, s-butanol, t-butanol and cyclohexanol; nitriles such as acetonitrile, propionitrile, n- or isobutyronitrile and benzonitrile; ketones such as acetone, methyl ethyl ketone, methyl isobutyl keton and cyclohexanone; amides such as N,N-dimethylformamide, N,N-dimethylacetoamide, N-methylformanilide, N-methylpyrrolidone and hexamethylphosphoramide; sulfoxides such as dimethyl sulfoxide; and sulfones such as sulfolane. The amount of the above organic solvent is 1 to 50 mass % of the total amount of the solvents. In view of recycling, it is easier to regenerate the solvent when the solvent is one kind of bicyclic compound solely in use for reaction purposes, purification purposes, coating purposes and the like.

The composition may contain a charge-transferable compound other than the triarylamine compound, a stabilizer, and the like depending on the purpose of use of the composition.

Next, a preparation method of the composition according to the present invention will be explained below. There is no particular limitation on the preparation method of the composition as long as the composition is prepared by dissolving the triarylamine compound in the bicyclic compound. In general, the composition can preferably be prepared by adding the triarylamine compound to the bicyclic compound and heating the resulting mixture by stirring or irradiation with ultrasonic wave.

The triarylamine compound is difficult to dissolve in ordinary solvents, but can be dissolved well in the bicyclic compound according to the present invention. The thus-obtained composition can thus be used for various application purposes. The suitable application purposes and conditions of the composition according to the present invention will be next explained below.

[Use for Reaction Purposes]

A solution reaction using a solvent is a common technique for organic synthesis of the triarylamine compound used in the present invention and for modification of the triarylamine compound with a substituent group. In the solution reaction, the amount of charge of the reaction substrate per unit reactor volume is limited to cause a deterioration in productivity if the solubility of the reaction substrate is low. In this respect, the bicyclic compound according to the present invention is useful as a reaction solvent because of high solubility of the triarylamine compound in the bicyclic compound. It is known that the triarylamine compound can be dissolved relatively well in e.g. tetrahydrofuran among ordinary solvents. However, tetrahydrofuran has a boiling point of 66° C. so that the reaction temperature is limited to 66° C. or lower in the solution reaction using tetrahydrofuran as the solvent. On the other hand, the bicyclic compound according to the present invention has a boiling point of 150° C. or higher so that the reaction can be performed at any temperatures desired by those skilled in the art. The composition according to the present invention is thus suitable for use in reactions of the triarylamine compound.

[Use for Purification Purposes]

The bicyclic compound according to the present invention is useful for purification of the triarylamine compound because of high solubility of the triarylamine compound in the bicyclic compound. The term “purification” herein refers to separation of the triarylamine compound from any impurity by purification operation in the present specification. More specifically, the purification refers to a process for improving the purity of the triarylamine compound by subjecting the composition containing at least the triarylamine compound, the bicyclic compound and any other unfavorable impurity to column operation, recrystallization operation, reprecipitation operation etc. By this process, the composition can be obtained with substantially no unfavorable impurity or a reduced amount of unfavorable impurity.

As one purification method, recrystallization operation will be explained below. As the solubility of the triarylamine compound increases with temperature, the recrystallization temperature is preferably 100 to 200° C. If the recrystallization temperature is lower than 100° C., it may not be possible to obtain sufficient solubility of the triarylamine compound or may take a long time for dissolution of the triarylamine compound. The triarylamine compound may be thermally decomposed if the recrystallization temperature is higher than 200° C. More preferably, the recrystallization temperature is preferably 110 to 150° C. The dissolution of the triarylamine compound by heating is preferably conducted in a nitrogen or argon atmosphere. The dissolution can be promoted by stirring or irradiation with ultrasonic wave. It is convenient to use an ordinary ultrasonic washing machine for ultrasonic wave irradiation. As mentioned above, the boiling point of tetrahydrofuran is 66° C. It is thus necessary, in the case of using tetrahydrofuran, to apply pressure by an autoclave etc. for dissolution of the triarylamine compound in a favorable temperature range. Further, it is difficult to conduct pipetting or filtering of the resulting solution under high-temperature conditions. On the other hand, the bicyclic compound according to the present invention has a boiling point of 150° C. or higher so that the recrystallization operation can be performed in the optimum range. One common example of recrystallization operation is to charge the bicyclic compound and crude triarylamine compound into a flask with a reflux condenser, stir the resulting composition at 130° C. in an argon atmosphere, filter the composition, slowly cool the composition to form a precipitate, filter out the precipitate, and then, dry the precipitate.

Column operation as another purification method can be performed by preparing the composition in which the triarylamine compound is dissolved in the bicyclic compound (the triarylamine compound is dissolved in an amount of 0.1 to 1 mass % in the bicyclic compound with the 5-membered heteroatom-containing ring and in an amount of 0.1 to 2 mass % in the bicyclic compound with the 5-membered hydrocarbon ring) in advance and flowing the composition through a column. The flowing conditions depend on the length, kind and packing material of the column. It is feasible to remove the solvent by a rotary evaporator etc. from the solution flowing out of the column. The concentrated solution can be subjected as it is to recrystallization operation.

[Use for Coating Purposes]

The composition according to the present invention is also suitable for use as a coating material (hereinafter occasionally just referred to as “coating material”) for formation of charge transfer layers of electrophotographic organic photoreceptors and positive hole transfer materials of organic EL elements (sometimes categorized as transfer layers). The transfer layer can be formed as desired by applying the coating material to any part where the transfer layer is to be formed, and then, drying the applied coating material. There is no particular limitation on the method for application of the coating material. The coating material can be applied by any known application process such as ink-jet process, dip coating process, spraying process, spin coating process, flow coating process, vapor deposition process, brush painting process, roll coating process, hand-painting process etc. The kind of the bicyclic compound and the component ratio of the coating material can be selected as appropriate according to the application process.

In the case of adopting the ink jet process as the application process, it is preferable that the boiling point of the bicyclic compound is 150 to 250° C. If the boiling point of the bicyclic compound is lower than this temperature range, the solvent may be volatized to cause clogging of ink-jet nozzles. It may be unfavorably necessary to take cost and time for removal of the solvent after the application of the coating material if the boiling point of the bicyclic compound is higher than this temperature range. In the case of using the bicyclic compound with the 5-membered heteroatom-containing ring, the coating material preferably contains 0.01 to 1 parts by mass, more preferably 0.05 to 0.5 parts by mass, of the triarylamine compound per 100 parts by mass of the bicyclic compound. In the case of using the bicyclic compound with the 5-membered hydrocarbon ring, the coating material preferably contains of the triarylamine compound is preferably contained in an amount of 0.01 to 2 parts by mass, more preferably 0.05 to 0.5 parts by mass, per 100 parts by mass of the bicyclic compound. An organic-EL-function improving aid, a binder resin, a coating-property improving agent and the like may preferably be added to the coating material as appropriate as desired by those skilled in the art.

### EXAMPLES

Hereinafter, the present invention will be described in more detail below by way of the following examples. It should be noted that the following examples are illustrative and are not intended to limit the present invention thereto.

[Preparation of Organic Semiconductor Compositions]

Organic semiconductor compositions were each prepared by putting predetermined amounts of triarylamine compound and bicyclic compound, as indicated in the following table, in a 10-cc screw vial, placing the screw vial in an ultrasonic washing machine filled with 50° C. hot water and mixing the triarylamine compound and the bicyclic compound by irradiation with ultrasonic wave for 60 minutes.

[Solubility Test]

The thus-obtained samples were tested for the solubility by visual observation.

◯: The triarylamine compound was completely dissolved.
Δ: Some of the triarylamine compound was undissolved.
X: Most of the triarylamine compound was undissolved.

[Pot Life Test]

Further, the thus-obtained samples were each closely sealed and kept light shielded for 30 days at room temperature. Then, each of the samples was tested for the pot life by visual observation. (The sample where the triarylamine compound was not completely dissolved was used by filtering the solid matter out with a filter paper (5C).)

◯: The solution was clear with no precipitation.
Δ: The solution had some turbidity even though no precipitation was seen in the solution.
X: Precipitation was seen in the solution.

### Example 1

The organic semiconductor composition was obtained by putting α-NPD (0.005 g) as the triarylamine compound and 1,3-dihydrobenzofurane (1 g) as the bicyclic compound with the 5-membered heteroatom-containing ring in the 10-cc transparent screw vial, placing the screw vial in the ultrasonic washing machine filled with 50° C. hot water and mixing the triarylamine compound and the bicyclic compound by irradiation with ultrasonic wave for 60 minutes. The obtained composition was subjected to solubility test and pot life test as mentioned above.

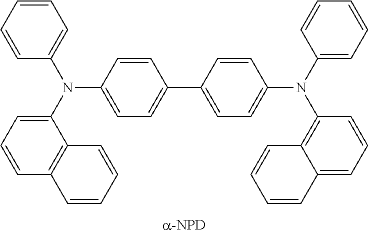 [SMILES: c1ccc(N(c2ccc(-c3ccc(N(c4ccccc4)c4cccc5ccccc45)cc3)cc2)c2cccc3ccccc23)cc1]

### Examples 2-10

The organic semiconductor compositions were obtained under the same conditions as those of Example 1, except for varying the kind of the bicyclic compound and changing the amount of the triarylamine compound, and then, were subjected to solubility test and pot life test as mentioned above.

The composition preparation conditions and test results of Examples 1 to 10 are indicated in TABLE 1.

TABLE 1

| | Bicyclic compound | | | | | |
|---|---|---|---|---|---|---|
| | | Boiling | Amount | Triarylamine | Solubility | Pot life |
| | Compound name | point (° C.) | (g) | compound (g) | test | test |
| Example 1 Example 2 | 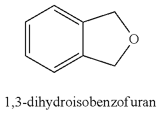 | 192 | 1 1 | 0.005 0.01 | ∘ ∘ | ∘ ∘ |
| Example 3 Example 4 | 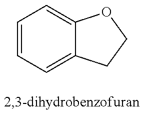 | 190 | 1 1 | 0.005 0.01 | ∘ ∘ | ∘ ∘ |
| Example 5 Example 6 | 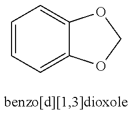 | 172 | 1 1 | 0.005 0.01 | ∘ ∘ | ∘ ∘ |
| Example 7 Example 8 | 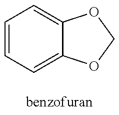 | 175 | 1 1 | 0.005 0.01 | ∘ ∘ | ∘ ∘ |
| Example 9 Example 10 | 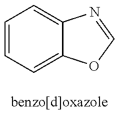 | 180 | 1 1 | 0.005 0.01 | ∘ ∘ | ∘ ∘ |

### Examples 11-13

The organic semiconductor compositions were each obtained by putting α-NPD (0.01 g) as the triarylamine compound and indene (1 g) as the bicyclic compound with the 5-membered hydrocarbon ring in the 10-cc transparent screw vial, placing the screw vial in the ultrasonic washing machine filled with 50° C. hot water and mixing the triarylamine compound and the bicyclic compound by irradiation with ultrasonic wave for 60 minutes. The obtained compositions were subjected to solubility test and pot life test as mentioned above.

### Examples 14-15

The organic semiconductor compositions were obtained under the same conditions as those of Examples 11 to 13, except for using indane as the bicyclic compound and changing the amount of the triarylamine compound, and then, were subjected to solubility test and pot life test as mentioned above.

The composition preparation conditions and test results of Examples 11 to 15 are indicated in TABLE 2.

TABLE 2

| | Bicyclic compound | | | | | |
|---|---|---|---|---|---|---|
| | | Boiling | Amount | Triarylamine | Solubility | Pot life |
| | Compound name | point (° C.) | (g) | compound (g) | test | test |
| Example 11 Example 12 Example 13 | 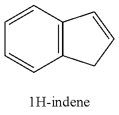 | 180 | 1 1 1 | 0.01 0.015 0.01 | ∘ ∘ ∘ | ∘ ∘ Δ |
| Example 14 Example 15 | 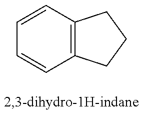 | 177 | 1 1 | 0.01 0.005 | ∘ ∘ | ∘ ∘ |

It is apparent from the results of TABLES 1 and 2 that: each of the bicylic compounds used as the solvent according to present invention had the capability of dissolving therein the triarylamine compound; and the resulting compositions each had long pot life and very good stability.

### Comparative Examples 1-6

The samples were prepared under the same conditions as those of Example 1, except for using other solvents in place of the bicyclic compound, and then, were subjected to solubility test and pot life test as mentioned above.

The composition preparation conditions and test results of Comparative Examples 1 to 6 are indicated in TABLE 3.

TABLE 3

| | Solvent | | | | | |
|---|---|---|---|---|---|---|
| | | Boiling | Amount | Triarylamine | Solubility | Pot life |
| | Compound name | point (° C.) | (g) | compound (g) | test | test |
| Comparative Example 1 Comparative Example 2 | 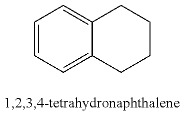 | 207 | 1 1 | 0.005 0.01 | ∘ Δ | X X |
| Comparative Example 3 | 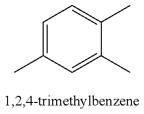 | 169 | 1 | 0.005 | Δ | X |
| Comparative Example 4 | 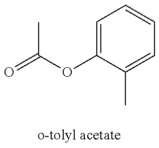 | 207 | 1 | 0.005 | Δ | X |
| Comparative Example 5 | 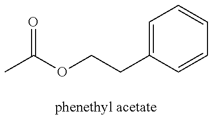 | 238 | 1 | 0.005 | Δ | X |
| Comparative Example 6 | 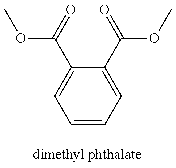 | 283 | 1 | 0.005 | Δ | X |

The solvents of Comparative Examples 1 to 6 were not capable of dissolving therein 0.5 mass % of the triarylamine compound because some undissolved triarylamine compound was visually observed in the solubility test. Further, each of the compositions using the solvents of Comparative Examples 1 to 6 had a stability problem because some precipitate was seen in the pot life test.

### Example 16

### Recrystallization Test

Into a 250-cc eggplant-shaped flask equipped with a reflux condenser and sealed with argon, TPD (5 g) of purity 99.80% as a triarylamine compound and 95 g of 2,3-dihydrobenzofuran as a bicyclic compound were charged. The resulting mixture was heated with stirring for 30 minutes by placing the flask in an oil bath of 140° C. The thus-obtained solution was filtered with a coarse glass filter in an argon atmosphere. The filtrate was slowly cooled down to room temperature and cooled for 24 hours in a freezer of −20° C., thereby forming 1.9 g of crystalline precipitate. The crystalline precipitate was dried under vacuum. It was confirmed by HPLC analysis of the crystalline precipitate (THF/water gradient method) that the purity of the triarylamine compound was improved to 99.98%.

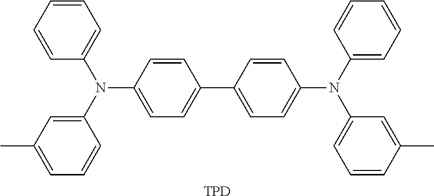

### Example 17

### Recrystallization Test

Into a 250-cc eggplant-shaped flask equipped with a reflux condenser and sealed with argon, TPD (5 g) of purity 99.80% as a triarylamine compound and 95 g of indane as a bicyclic compound were charged. The resulting mixture was heated with stirring for 30 minutes by placing the flask in an oil bath of 140° C. The thus-obtained solution was filtered with a coarse glass filter in an argon atmosphere. The filtrate was slowly cooled down to room temperature and cooled for 24 hours in a freezer of −20° C., thereby forming 1.8 g of crystalline precipitate. The crystalline precipitate was dried under vacuum. It was confirmed by HPLC analysis of the crystalline precipitate (THF/water gradient method) that the purity of the triarylamine compound was improved to 99.98%.

### Example 18

### Pot Life Test

The same experiment as that of Example 6 was carried out using 0.05 g of 1,1-bis[4-[N,N-di(p-tolyl)amino]phenyl]cyclohexane and 1,3-dihydroisobenzofuran (1 g). The resulting solution was clear with no precipitation even after a lapse of 60 days.

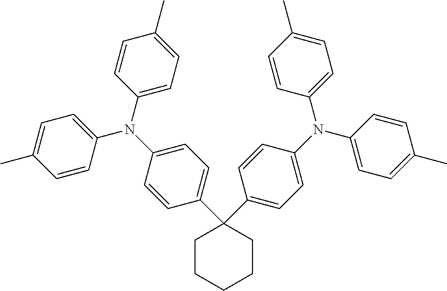

### 1,1-bis[4-N,N-di(p-tolyl)amino]phenylcyclohexane

### Example 19

### Pot Life Test

The same experiment as that of Example 6 was carried out using 0.05 g of 1,1-bis[4-[N,N-di(p-tolyl)amino]phenyl]cyclohexane and indane (1 g). The resulting solution was clear with no precipitation even after a lapse of 60 days.

### Example 20

### Coating Test

TDP (1 g) and indane (99 g) were put into a conical flask and mixed together by irradiation with ultrasonic wave for 30 minutes at 50° C. with the use of an ultrasonic washing machine. After confirming that the TDP was dissolved in the indane, the solution was cooled down to room temperature. The solution was then spin coated at 1500 rpm on a clean glass and dried by a hot plate. It was confirmed by visual observation that the coating was uniformly applied to the glass.

As described above, it is possible according to the present invention to obtain the stable organic semiconductor composition in which the triarylamine compound is sufficiently dissolved.

1. A composition comprising at least a triarylamine compound and at least one bicyclic compound selected from the group consisting of those of the general formulas [1] to [4], wherein the triaryl amine compound is dissolved in said at least one bicyclic compound 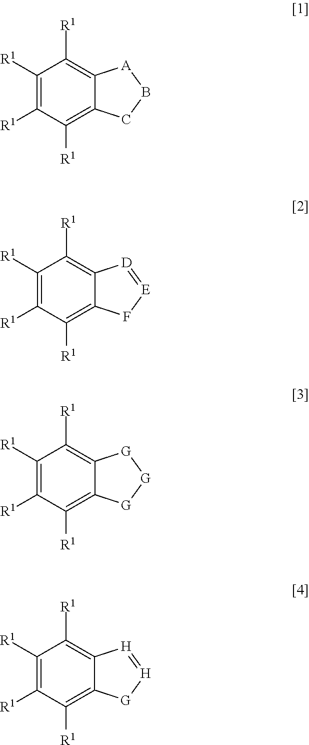
where R¹ each independently represents a hydrogen atom, a methyl group, an ethyl group, a methoxy group, an ethoxy group, a fluorine atom or a chlorine atom; A, B, C and F each independently represents either —CR²₂—, —O— or —NR²—; D and E each independently represents either —CR²═ or —N═; G represents —CR²₂—; H represents —CR²═; and R² represents a hydrogen atom, a methyl group or a halogen atom.

2. The composition according to claim 1, wherein the triarylamine compound has two or more tertiary nitrogen atoms.

3. The composition according to claim 2, wherein different two of the tertiary nitrogen atoms of the triarylamine compound are bonded by any of structures of the following formulas (a) to (e) 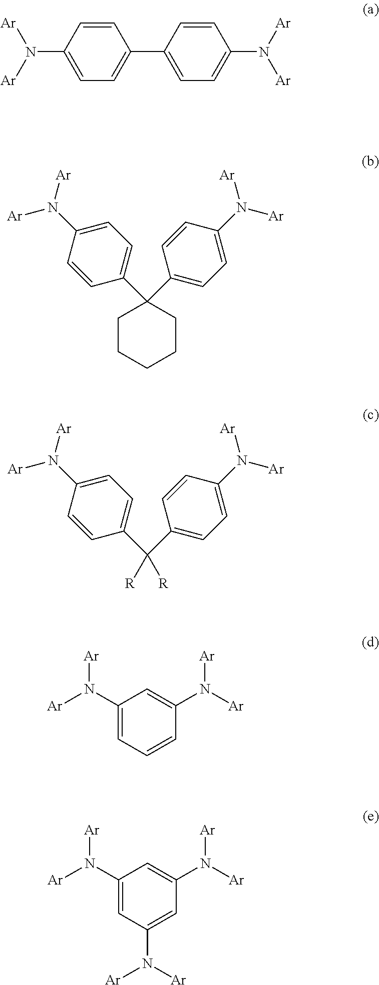
where R represents a C₁-C₈ alkyl group; and Ar each independently represents an aryl group and can be of the same kind or different kinds.

4. The composition according to claim 1, wherein the bicyclic compound has a boiling point of 150 to 250° C.

5. The composition according to claim 1, wherein the triarylamine compound is a charge transfer material.

6. The composition according to claim 1, wherein the composition is a coating material for forming a charge transfer layer or a positive hole transfer layer.

7. The composition according to claim 6, wherein the coating material is for ink-jet process.

8. The composition according to claim 1, wherein the composition is for use in reaction or purification.

9. The composition according to claim 1, wherein the triarylamine compound is contained in an amount of 0.01 to 2 parts by mass per 100 parts by mass of the at least one bicyclic compound.

10. The composition according to claim 1, wherein the triarylamine compound is contained in an amount of at least 0.5 mass %.

11. The composition according to claim 1, wherein said at least one bicyclic compound is one kind of compound or two or more kinds of compounds selected from the group consisting of benzofuran, 2,3-dihydrobenzofuran, benzo[d][1,3]dioxole, 1,3-dihydroisobenzofuran, 1H-isoindole, 3H-indole, benzo[d]oxazole, 3H-indazole, 2-methylisoindoline, 1-methylindoline, indene and indane.
